(19) United States
(12) Patent Application Publication
(10) Pub. No.: US 2026/0173955 A1
(43) Pub. Date: Jun. 18, 2026

(54) SEMICONDUCTOR DEVICE INCLUDING VERTICAL WIRE BONDS

(71) Applicant: Sandisk Technologies, Inc., Milpitas, CA (US)

(72) Inventors: Cindirella Quinit Noromor, La Union (PH); Hubert Tolentino Helera, Laguna (PH); Muhammad Faizul Bin Mohd Yunus, Penang (MY); Muhamad Ridhwan Hafiz bin Rosdi, Penang (MY)

(73) Assignee: Sandisk Technologies, Inc., Milpitas, CA (US)

(21) Appl. No.: 18/982,848

(22) Filed: Dec. 16, 2024

(51) Int. Cl. H01L 23/00; H01L 25/04; H10B 80/00

(52) U.S. Cl. CPC H10W 90/00; H10B 80/00; H10W 72/9415; H10W 90/752; H10W 90/754

(57) ABSTRACT

A semiconductor device incudes semiconductor dies which are diced from a wafer by making a first cut along a y-axis, and a pair of cuts along an x-axis. When the wafer is diced, for example in a stealth dice before grinding process, a first cut is made along the x-axis to sever the die bond pads, leaving a portion of the die bond pads exposed at an edge of the diced semiconductor die. A second cut along the x-axis removes a residual portion of semiconductor die from the next adjacent die resulting from the first cut. The exposed die bond pads allow the dies to be vertically stacked with the die bond pads exposed in a vertical edge. The dies may then be bonded by a vertical wire bonding technique.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

Semiconductor memory may be provided within a semiconductor package, which protects the semiconductor memory and enables communication between the memory and a host device. Examples of semiconductor packages include system-in-a-package (SiP) or multichip modules (MCM), where a plurality of die are mounted and interconnected on a small footprint substrate.

Semiconductor dies are often stacked in a package in an offset stepped configuration, so that the die bond pads for each die in the stack are accessible for wire bonding. However, this type of layout has a few disadvantages. First, given the horizontal offset, the footprint of the offset dies together takes up a lot of space on the substrate. Second, where dies are stacked without complete overlap with the die below, warping of the upper die becomes a problem. It is known to vertically stack dies and form electrical connections on the vertical face. However, current electrical connections schemes require complicated printing or other electrical lead formation processes.

### DESCRIPTION OF THE DRAWINGS

FIG. 1 is a flowchart for forming a semiconductor die according to embodiments of the present technology.

FIG. 2 is a front view of a semiconductor wafer showing a first major surface of the wafer.

FIG. 3 is an enlarged view of a portion of the wafer showing die bond pads formed in a kerf area of the wafer.

FIGS. 4 and 5 are cross-sectional edge and top views showing a die bond pad and internal components within the wafer according to a first embodiment.

FIGS. 6 and 7 are cross-sectional edge and top views showing a die bond pad and internal components within the wafer according to a second embodiment.

FIGS. 8 and 9 are cross-sectional edge and top views showing a die bond pad and internal components within the wafer according to a third embodiment.

FIGS. 10 and 11 are cross-sectional edge and top views showing a die bond pad and internal components within the wafer according to a fourth embodiment.

FIGS. 12 and 13 illustrate a stealth dicing before grinding laser process for dicing a semiconductor wafer.

FIG. 14 illustrates a finished semiconductor die including die with edge bond pads according to a first embodiment of the present technology.

FIG. 15 illustrates a finished semiconductor die including die with edge bond pads according to an alternative embodiment of the present technology.

FIG. 16 is a perspective view of a semiconductor device including semiconductor dies stacked on a substrate according to embodiments of the present technology.

FIGS. 17-18 are perspective and edge views of a semiconductor device including bond wires formed upward from the substrate according to embodiments of the present technology.

FIGS. 19-20 are perspective and edge views of a semiconductor device including vertical wires bonded to the die bond edge pads according to embodiments of the present technology.

FIG. 21 is an edge view of an alternative embodiment of the present technology.

FIG. 22 is a front view of an encapsulated semiconductor package according to embodiments of the present technology.

### DETAILED DESCRIPTION

The present technology will now be described with reference to the figures, which in embodiments, relate to semiconductor dies which are diced from a wafer by making a first cut along a y-axis, and a pair of cuts along an x-axis. When the wafer is diced, for example in a stealth dice before grinding process, a first cut is made along the x-axis to sever the die bond pads, leaving a portion of the die bond pads exposed at an edge of the diced semiconductor die. A second cut along the x-axis removes a residual portion of semiconductor die from the next adjacent die resulting from the first cut. The exposed die bond pads allow the dies to be vertically stacked with the die bond pads exposed in a vertical edge. The dies may then be bonded by a vertical wire bonding technique.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

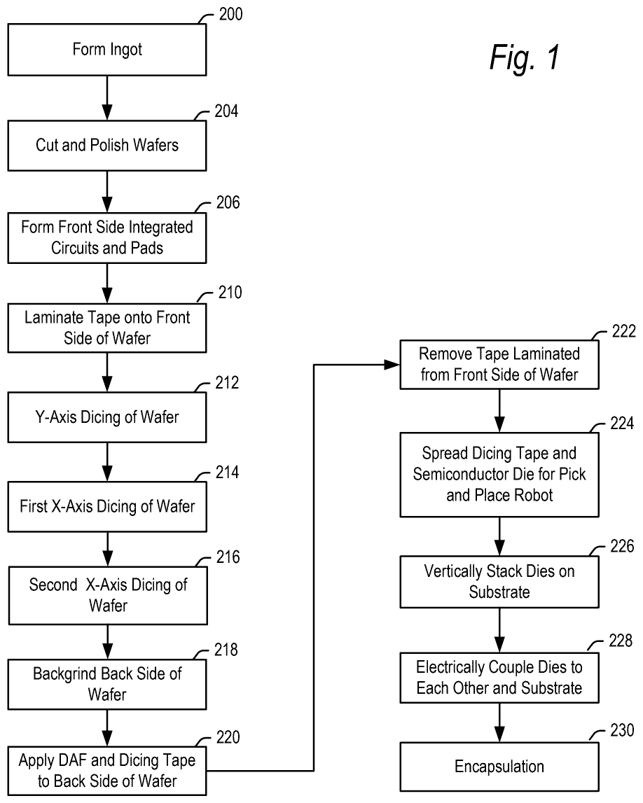

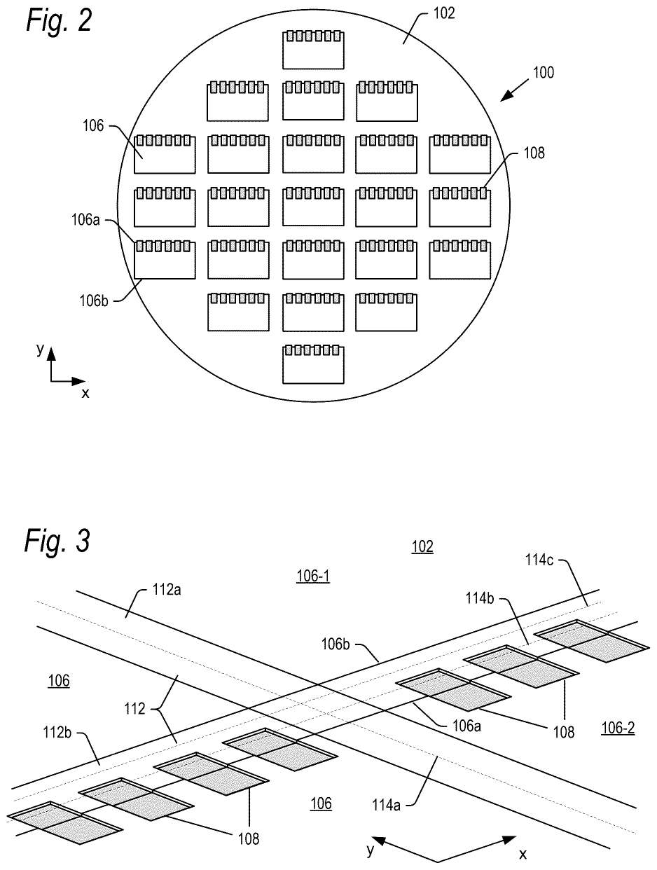

An embodiment of the present technology will now be explained with reference to the flowchart of FIG. 1, and the views of FIGS. 2-22. Referring initially to the flowchart of FIG. 1, a semiconductor wafer 100 may start as an ingot of wafer material which may be formed in step 200. In one example, the ingot from which the wafers 100 are formed may be monocrystalline silicon grown according to either a Czochralski (CZ) or floating zone (FZ) process. However, wafer 100 may be formed of other materials and by other processes in further embodiments.

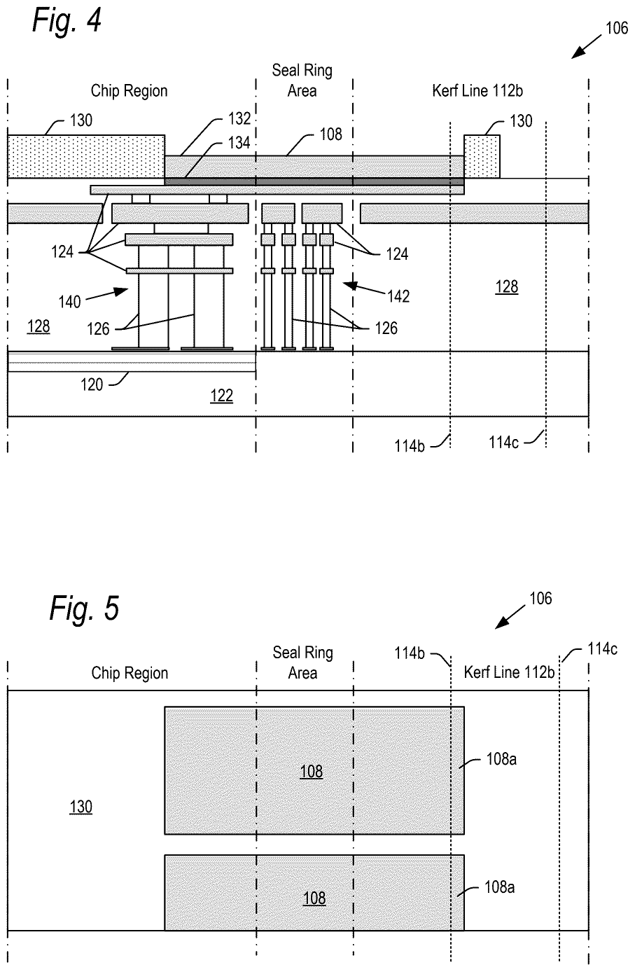

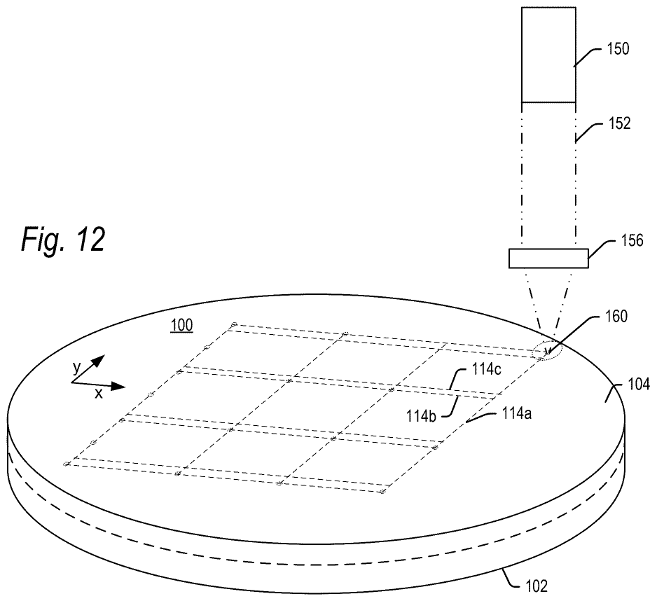

In step 204, the semiconductor wafer 100 may be cut from an ingot and polished on both the first major surface 102 (FIG. 2), and second major surface 104 (FIG. 12) opposite surface 102, to provide smooth surfaces. In step 206, the first major surface 102 may undergo various processing steps to divide the wafer 100 into respective semiconductor die 106 (one of which is numbered in FIGS. 2 and 3), and to form integrated circuits of the respective semiconductor die 106 on and/or in the first major surface 102. These various processing steps may include metallization steps depositing metal contacts including die bond pads 108 (one of which is numbered in FIG. 2) exposed on the first major surface 102. The metallization steps may further include depositing metal interconnect layers and vias within the wafer. These metal interconnect layers and vias may be provided for transferring signals to and from the integrated circuits, and to provide structural support to the integrated circuits as explained below with respect to FIGS. 4-11.

The number of semiconductor dies 106 shown on wafer 100 in FIG. 2 is for illustrative purposes, and wafer 100 may include more or less semiconductor dies 106 than are shown in further embodiments. Similarly, the number of bond pads 108 on each semiconductor die 106 are shown for illustrative purposes, and each die 106 may include more die bond pads than are shown in further embodiments. Each semiconductor die 106 may include a proximal end 106a including the bond pads 108, and a distal end 106b opposite the proximal end 106a. The die bond pads 108 may for example be formed of aluminum, or alloys thereof, but the die bond pads 108 may be formed of other materials in further embodiments. In embodiments, the integrated circuits may operate as NAND flash memory semiconductor die such as for example Bit Cost Scaling (BiCS) memory dies, though other types of integrated circuits are contemplated.

In embodiments, each die bond pad 108 may have a length and width of approximately 70 μm, though the length and width may vary in further embodiments, proportionately or disproportionately to each other. In accordance with aspects of the present technology, die bond pads 108 may be formed at least partially within the a scribe area, or kerf area, provided between semiconductor die 106 on wafer 100. FIG. 3 is a perspective view showing a portion of the first major surface 102 of the wafer 100. The wafer 100 may include a kerf area 112 comprising vertically oriented kerf lines 112a and horizontally oriented kerf lines 112b. The kerf area 112 has been traditionally reserved as a border around active areas of the semiconductor die where a cut may be made to separate the semiconductor die from each other and the wafer 100. As such, the kerf area 112 has traditionally not formed part of the active area of semiconductor die 106 usable to form integrated circuits.

In some traditional dicing techniques such as sawing, material is removed from the wafer during the cut, and the cut is also not precisely controllable. As such, the kerf area 112 is traditionally larger than the area required to make the actual cut. Some wafer fabrication technologies provide for example a 70 μm kerf line width, while other wafer fabrication technologies provide for example a 170 μm kerf line width. The kerf lines 112a, 112b may have these or other widths in different embodiments.

As explained below, embodiments of the present technology use stealth dicing before grinding, which is a precise cutting method that removes little or none of the wafer when dicing the wafer. FIG. 3 further shows a vertical dicing line 114a (along the y-axis), and first and second horizontal dicing lines 114b and 114c (along the x-axis) indicating the lines along which die 106 will be cut from wafer 100 as explained below.

In accordance with aspects of the present technology, a first portion of the die bond pads 108 may be formed within the usable area of the semiconductor die 106, and a second portion of the die bond pads 108 may be formed within the horizontal kerf lines 112b. The amount by which the die bond pads 108 extend into the horizontal kerf lines 112b may vary in embodiments, but is sufficient so that when the semiconductor die 106 are diced from the wafer 100, the dicing lines 114b pass through the second portion of the die bond pads 108 in the horizontal kerf lines 112b. In one example, one-half of the die bond pad may extend into the horizontal kerf lines 112b. If the die bond pads are 70μm long, 35 μm may be formed in the horizontal kerf lines. However, this amount is provided by way of example only, and, as explained below, more of the die bond pads 108 may be formed in the horizontal kerf line 112b in further embodiments.

Thus, when the semiconductor die 106 are diced from the wafer 100 along the dicing cut lines 114b, each of the die bond pads 108 are severed, leaving a portion of the die bond pads 108 exposed at the diced edge at the proximal end 106a of each semiconductor die 106.

After dicing along cut lines 114b, a residual portion of each die bond pad 108 may remain in the distal end 106b of the semiconductor die 106. Thus, in FIG. 3, if only a single cut along cutline 114b were made, a portion of the die bond pad from die 106-2 would remain as a residual part of die 106-1. However, in accordance with further aspects of the present technology, a second cut, along cut line 114c, is made to remove this residual portion of each die. Thus, the upon completion of both dicing cuts 114b and 114c, the die bond pads are at the edge of die 106-2, but no portion of the die 106-2 remains part of die 106-1. This effectively reduces the size of the resulting semiconductor dies 106. The residual portion of each die cut by cutline 114c is discarded.

In general, the second portion of the die bond pads 108 may extend less than half way into the horizontal kerf lines 112b. In such embodiments, the cut line 114b may be nearer to the semiconductor die proximal end 106a than to distal end 106b within the kerf lines 112b as shown in FIG. 3. In further embodiments, the second portion of the die bond pads 108 may extend more than halfway into the horizontal kerf lines 112b. In such embodiments, the cut line 114b may be nearer to the semiconductor die proximal end 106a as shown in FIG. 3, or the cut line 114b may be made down the middle of the horizontal kerf lines 112b.

FIGS. 4 and 5 are cross-sectional side and top views of the wafer 100 at the proximal ends 106a of the semiconductor die 106 shown for example in FIG. 3. Each semiconductor die 106 may include integrated circuits 120 formed in and/or on a substrate layer 122 within a chip region of the semiconductor wafer. After formation of the integrated circuit 120, multiple layers of metal interconnects 124 and vias 126 may be formed sequentially in layers of a dielectric film 128. As is known in the art, the metal interconnects 124, vias 126 and dielectric film layers 128 may be formed a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 124 may be formed of a variety of electrically conductive metals including for example copper and copper alloys as is known in the art, and the vias may be lined and/or filled with a variety of electrically conductive metals including for example tungsten, copper and copper alloys as is known in the art.

A passivation layer 130 may be formed on top of the upper dielectric film layer 128. The passivation layer 130 may be etched to form the die bond pads 108. Each die bond pad 108 may include a contact layer 132 formed over a liner 134. As is known in the art, the contact layer 132 may be formed for example of copper, aluminum and alloys thereof, and the liner 134 may be formed for example of a titanium/titanium nitride stack such as for example Ti/TiN/Ti, though these materials may vary in further embodiments. The bond pads 108 (contact layer plus liner) may have a thickness of 720 nm, though this thickness may be larger or smaller in further embodiments.

The metal interconnects 124 and vias 126 may be used to form conductive nodes 140 as is known in the art within the chip region for transferring signals and voltages between the die bond pads 108 and integrated circuits 120. The metal interconnects 124 and vias 126 may also be used to form a seal ring 142 as is known in the art within a seal ring area. The seal ring 142 may surround the integrated circuits 120 and conductive nodes 140, and provide mechanical support to prevent damage to the integrated circuits 120 and conductive nodes 140 for example during dicing of the wafer 100.

In the embodiments of FIGS. 3-5, the die bond pads 108 are formed partially in the chip regions, seal ring areas and horizontal kerf lines 112b on wafer 100. The chip regions and seal ring areas may together be referred to herein as the active area of a semiconductor die 106. FIGS. 3-5 also show dicing line 114b representing a line along which the semiconductor dies 106 are cut from wafer 100. As shown, the dicing line 114b cuts through the die bond pads 108 to leave an edge of the die bond pads 108 exposed at the edge of each semiconductor die 106 upon dicing from wafer 100. This exposed edge of the die bond pads 108 may be referred to herein as edge 108a. In one embodiment, the die bond pads 108 may be severed 1 μm to 5 μm from a proximal edge of the die bond pads, though the cut may be made closer or farther from the proximal edge of the die in further embodiments. The second cut along cutline 114c severs the residual portion of die 106 which would otherwise form part of the next adjacent die 106.

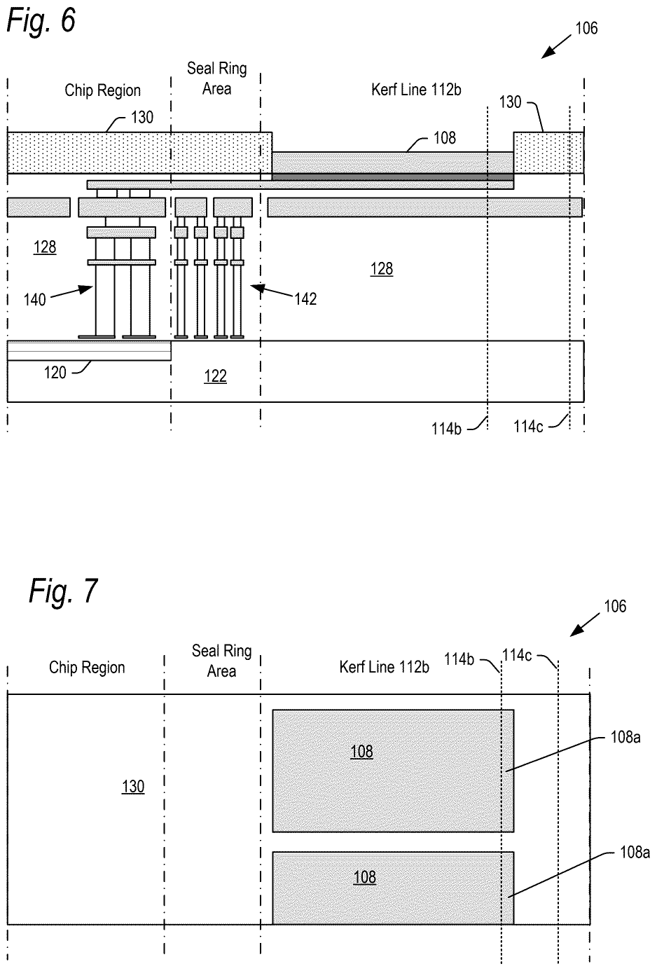

FIGS. 6 and 7 are cross-sectional and top views of a further embodiment of the present technology. In this embodiment, each semiconductor die 106 may include metal interconnects 124 and vias 126 forming the conductive nodes 140 and seal rings 142 as described above. However, in this embodiment, the die bond pads 108 are formed within the passivation layer 130 entirely within the horizontal kerf lines 112b on wafer 100. A portion of the passivation layer 130 may also extend into the horizontal kerf lines 112b, though it need not in further embodiments. In this embodiment, the die bond pads 108 may have the same length as in the embodiment of FIGS. 4 and 5, or the die bond pads 108 may have different lengths, such as for example shorter.

FIGS. 6 and 7 also show dicing line 114b representing the line along which the semiconductor die 106 are cut from wafer 100. As shown, the dicing line 114b cuts through the die bond pads 108 to leave the edge 108a of the die bond pads 108 exposed at the edge of each semiconductor die 106 upon dicing from wafer 100. Again, the second cut along cutline 114c severs the residual portion of die 106 which would otherwise form part of the next adjacent die 106.

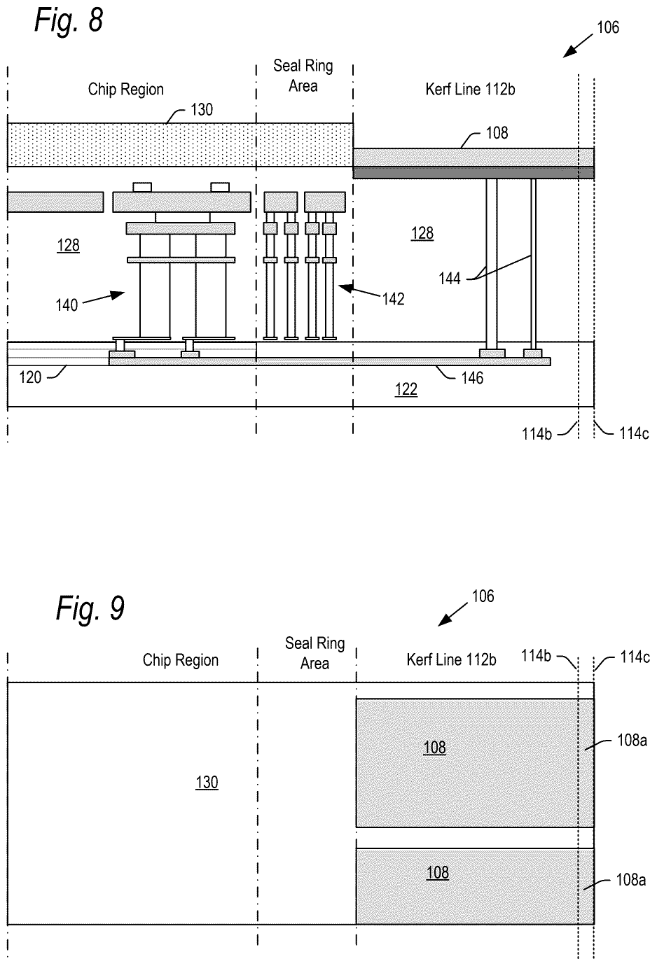

FIGS. 8 and 9 are cross-sectional and top views of a further embodiment of the present technology. In this embodiment, each semiconductor die may include the conductive nodes 140 and seal rings 142 as described above, and a die bond pad 108 formed entirely within the horizontal kerf lines 112b as described above. However, in the embodiment of FIGS. 8 and 9, the die bond pads 108 are electrically connected to the conductive nodes 140 through vias 144 and metal interconnects 146. As shown, the vias 144 may be formed extending down through all dielectric film layers 128 and into the substrate layer 122. Metal interconnects 146 may be formed within the substrate layer 122 extending between the vias 144 and metal interconnects of the conductive nodes 140, beneath the seal rings 142. In this embodiment, the passivation layer 130 may or may not extend into the horizontal kerf lines 112b. In this embodiment, the die bond pads 108 may have the same length as in the embodiment of FIGS. 4 and 5, or the die bond pads 108 may have different lengths, such as for example shorter.

FIGS. 8 and 9 also show dicing line 114b representing the line along which the semiconductor die 106 are cut from wafer 100. As shown, the dicing line 114b cuts through the die bond pads 108 to leave the edge 108a of the die bond pads 108 exposed at the edge of each semiconductor die 106 upon dicing from wafer 100. Again, the second cut along cutline 114c severs the residual portion of die 106 which would otherwise form part of the next adjacent die 106.

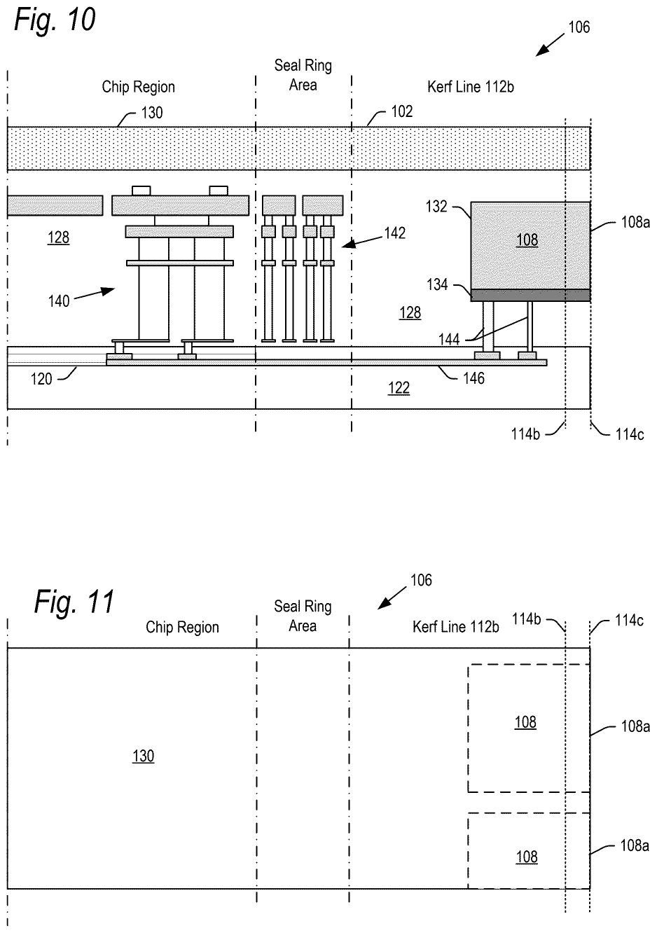

FIGS. 10 and 11 are cross-sectional and top views of a further embodiment of the present technology. In this embodiment, each semiconductor die may include the conductive nodes 140 and seal rings 142 as described above, and die bond pads 108 formed entirely within the horizontal kerf lines 112b. However, in this embodiment, the die bond pads 108 may be formed entirely beneath the major surface 102 of the wafer 100. In this embodiment, the passivation layer 130 may be a continuous (uninterrupted) layer on the surface 102 of the wafer 100. The die bond pads 108 may be formed entirely within the dielectric film layers 128 beneath the passivation layer 130.

In this embodiment, the exposed edges 108a of die bond pads 108 are the only portions of the die bond pads 108 used for electrical connection to the semiconductor die 106 within a semiconductor package as explained below. As such, the die bond pads 108 may be formed entirely within the horizontal kerf lines 112b, having a shorter length than the die bond pads 108 in the embodiments of FIGS. 4-9. However, the die bond pads 108 in the embodiment of FIGS. 10 and 11 may have the same length as the die bond pads 108 in the embodiments of FIGS. 4-9. The contact layer 132 is shown as having a greater thickness than in previously described embodiments, but the thickness of contact layer 132 may alternatively be the same as earlier described embodiments.

Upon dicing of the semiconductor die 106 from the wafer 100 along dicing lines 114b, the die bond pads 108 are severed to leave the edge 108a of the die bond pads 108 exposed at the edge of each semiconductor die 106 upon dicing from wafer 100. However, in this embodiment, the edges 108a of the die bond pads 108 are beneath the surface of semiconductor die 106, between the major surfaces 102 and 104. Again, the second cut along cutline 114c severs the residual portion of die 106 which would otherwise form part of the next adjacent die 106.

In the embodiment of FIGS. 10 and 11, the die bond pads 108 may include contact layers 132 formed over liners 134 as described above. Additionally, the die bond pads 108 may be electrically connected to the conductive nodes 140 through vias 144 and metal interconnects 146 formed down through one or more dielectric layers 128 into substrate layer 122 beneath the seal rings 142 as described above with respect to FIGS. 8 and 9. Alternatively, metal interconnects 124 and vias 126 may be provided within dielectric film layers 128 connecting the die bond pads 108 to the conductive nodes 140 above the seal rings 142 in further embodiments.

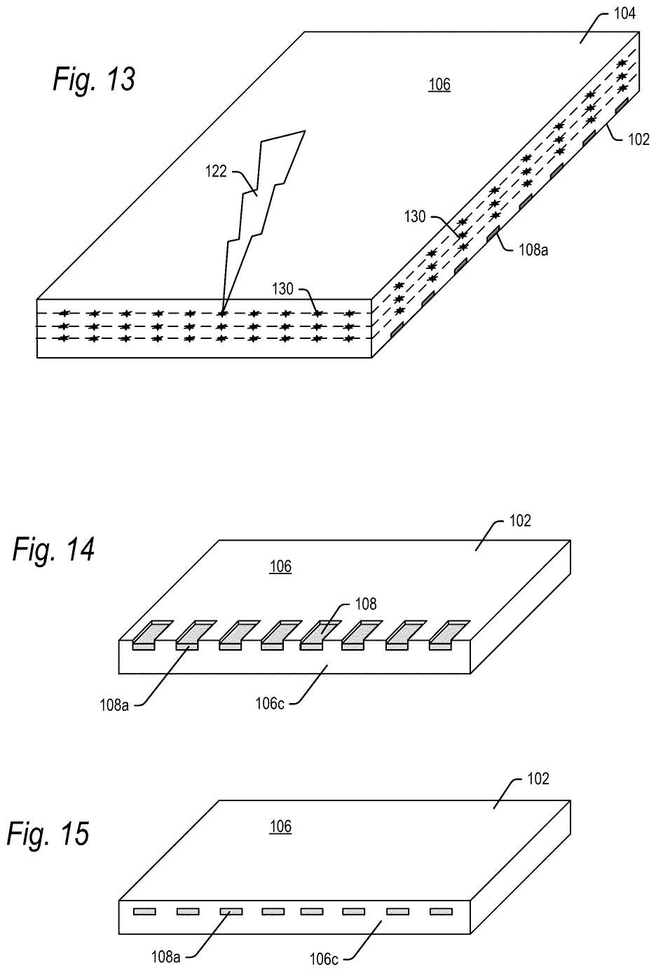

After formation of the integrated circuits 120 and metal conducting layers in step 206, a layer of tape may be laminated onto the active major surface 102 in step 210. The wafer 100 may then be turned over, and diced in step 212. Embodiments of the present technology dice the wafer 100 using a stealth dicing before grinding step, which will now be explained with reference to FIGS. 12 and 13. The wafer 100 may be supported on a chuck or other support surface (not shown) with the second major (inactive) surface 104 facing away from the support surface. A laser 150 may then emit a pulsed laser beam 152 at a wavelength that transmits through the second major surface 104 of the wafer 100, for example at infrared or near-infrared wavelengths. The pulsed laser beam may be focused to a point beneath the wafer's surface 104 using an optical system, for example including one or more collimating lenses 156. When the laser beam hits a peak power density at the focal point, the wafer absorbs the energy, and a pinpoint hole 160 is created beneath the wafer's surface.

The laser may be moved along the kerf lines 112a and 112b in a plane of the wafer and activated at a number of points so that a number of closely situated pinpoint holes 160 are formed at an intermediate depth of the wafer (between the first and second major surfaces 102, 104 of the wafer). In particular, the laser is moved along cutlines 114a in step 212 to dice the wafer along the y-axis. Then the laser is moved along cutline 114b to make a first dice through the die bond pads 108 along the x-axis in step 214. Then the laser is moved along cutline 114c to make a second cut along the x-axis in step 216 to remove a residual portion and to shorten each semiconductor die. It is understood that these cuts in step 212, 214 and 216 may be made in any order.

As discussed above, the cut along cutline 114a in the y-direction defines first and second opposed sides of each semiconductor die. The pair of cuts along cutline 114b and 114c in the x-direction define the third and fourth opposed sides of each semiconductor die. As noted above, the cut along cutline 114b passes through each of the die bond pads to sever the die bond pads and leave them exposed at the vertical edge of each die. The cut along cutline 114c removes a residual portion of each die so that it gets removed from the distal end 106b of each semiconductor die. This also effectively shortens the x-dimension of each die.

FIG. 13 shows the laser 150 having created layers of pinpoint holes 160 at three different depths of the wafer 100 in FIG. 13, but the laser may form one or more layers of pinpoint holes 160 at one or more depths in further embodiments. While FIG. 13 appears to show a diced semiconductor die 106, the die 106 may still be part of wafer 100 while the stealth dicing process is performed (and individual pinpoint holes 160 would not be visible to the eye upon inspection of wafer 100).

After the stealth dicing steps 212-216, the wafer 100 may be diced or partially diced. The wafer may then be thinned in step 218 using a grinding wheel (not shown) applied to the second major surface 104. The grinding wheel may thin the wafer 100 from, for example, 780 μm to its final thickness of for example about 25 μm to 36 μm. It is understood that the wafer 100 may be thinner or thicker than this range after the backgrind step in further embodiments. In addition to thinning the wafer 100, the vibrations from the backgrind step may cause cracks at the pinpoint holes 160 to propagate toward the first and second major surfaces 102, 104 of the wafer 100 to complete the dicing along dicing lines 114 of any semiconductor die not fully diced after the stealth dice before grinding step.

It is understood that the wafer may be diced by methods other than stealth dice before grinding in further embodiments, including for example by saw, laser or waterjet cutting methods. In such embodiments, the wafer may be diced before or after the backgrind step.

After completion of the backgrind step 218, a layer of die attach film (DAF) adhered to a flexible dicing tape may be applied onto the second major surface 104 of the wafer 100 in step 220. The wafer 100 may then be turned over and supported on a chuck or other support surface, and the lamination tape on the first major surface 102 of the wafer 100 may be removed in step 222. Once on the chuck, the flexible dicing tape may be stretched along orthogonal axes to separate the individual semiconductor die 106 in step 224 to allow the individual semiconductor die 106 to be removed by a pick and place robot for inclusion in a semiconductor package. It is conceivable that the die 106 are not fully diced at completion of the backgrind step 214. In this event, stretching of the dicing tape in step 220 will complete dicing of the semiconductor die along the dicing lines 114. The residual portions (between the cuts 114b and 114c) may be left on the dicing tape once the dies 106 are removed.

FIG. 14 shows a semiconductor die 106 after separation from wafer 100. The die 106 includes die bond pads 108 at a major surface 102 of the die 106, and the edges 108a of the die bond pads 108 exposed at an edge 106c of the semiconductor die 106. FIG. 15 shows the die bond pads 108 beneath the major surface 102 of the die 106, and the edges 108a of the die bond pads 108 exposed at the edge 106c of the semiconductor die 106.

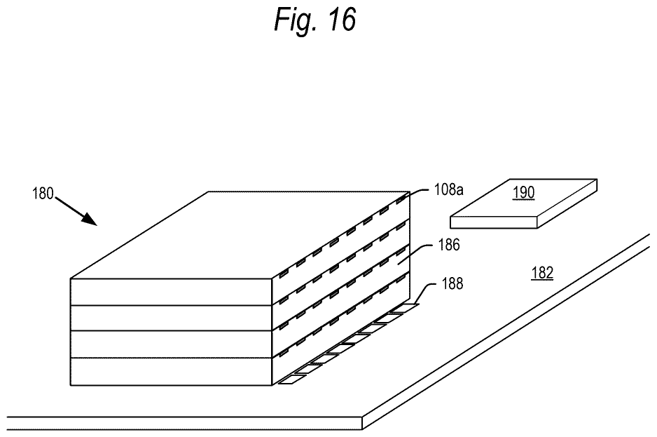

In accordance with further aspects of the present technology, the semiconductor dies 106 may be stacked in a cubic semiconductor device having a minimal footprint. Embodiments of such a semiconductor device will now be described with reference to FIGS. 16-21. These embodiments may use any of the semiconductor dies shown for example in FIGS. 4-15. In step 226, a number of semiconductor dies 106 may be stacked on a signal-carrier medium such as a substate 182 shown partially in FIG. 16. The dies 106 may be stacked in a cube, with no offset from each other, forming for example a chip-scale package. While four semiconductor die 106 are shown, it is understood that device 180 may include various numbers of semiconductor dies including for example 2, 4, 8, 16, 32 and 64 semiconductor dies. Semiconductor device 180 may include other numbers of semiconductor die in further embodiments.

In the embodiment of FIG. 16, the die edges including the die bond pads 108 may be stacked to form a vertical, planar surface 186, with bond pad edges 108a exposed at the surface 186. The dies 106 may be slightly offset from each other in further embodiments. This still defines a vertical surface 186, but it is not planar. The substrate 182 incudes contact pads 188 aligned adjacent to the vertical surface 186.

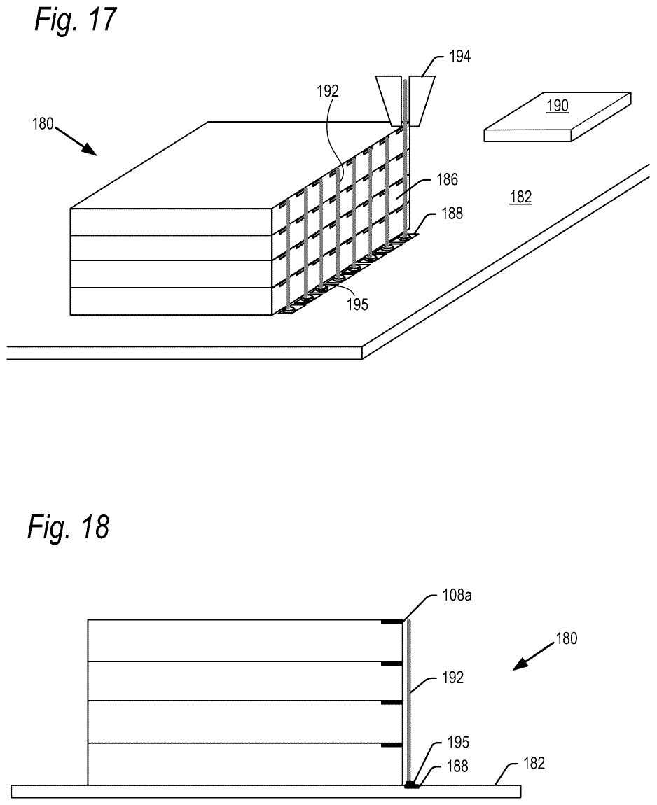

In accordance with a further aspect of the present technology, the dies 106 may be electrically coupled to each other and the substrate 182 by vertical wire bonds on the vertical surface 186 in step 228. In embodiments, the vertical wire bonds may be formed by non-contact soldering as will now be explained with reference to FIGS. 17-20.

Initially, the vertical surface 186 may be cleaned, including bond pad edges 108a. In embodiments, a small amount of b-stage solder may be applied to each bond pad edge 108a on the vertical surface 186. Next, vertical wires 192 may be formed up from the contact pads 188 on substrate 182 as shown in the perspective and edge views of FIGS. 17 and 18. The wires are formed by a wire bond capillary 192 up from each contact pad 188. The capillary initially forms a ball bond 195 on a first contact pad 188, and then feeds the wire 192 upward, aligned with and adjacent to a first row of edge bond pads 108a. The wire is slightly spaced from the vertical surface 186, for example 2 μm to 5 μm. The wire may or may not lie in contact with the b-stage solder on each bond pad edge 108a.

The first wire 192 is formed to a height of the edge bond pad 108a in the uppermost die 106. The wire bond capillary may then cut the wire and repeat the process on the next adjacent contact pad 188. This process continues until a wire 192 is formed aligned with and adjacent to each column of edge bond pads 108a, as shown in FIG. 17. The number of columns of edge bond pads 108a and wires 192 is shown by way of example only and there may be other numbers of edge bond pad columns and wires 192 in further embodiments.

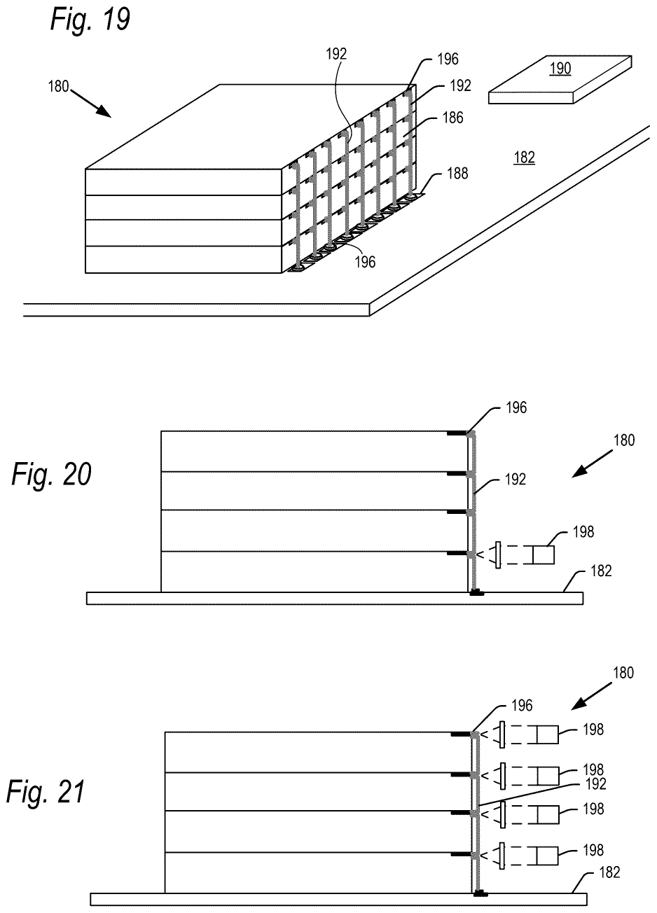

Referring now to FIGS. 19 and 20, the wires 192 are next bonded to edge bond pad 108a to which each is adjacent. In embodiments, this may be performed by a non-contact soldering process. In one such example, bonds 196 are formed at each bond pad edge 108a and the wire 192 along each column. The bonds 196 may be formed by localized non-contact heating of the wire 192, for example by a laser 198 moving down the column. The laser may be aligned at a site of a bond pad edge 108a with an optical system and activated. The activated laser heats the b-stage solder and the wire at that site, and forms a bond between the bond pad edge 108a and the wire 192 at that site as the solder cures to a c-stage. This process may start at the top of a column and proceed down the stack. Once a column is completed, the laser 198 (or the substrate 182) may be repositioned and the process repeated at the next column of bond pad edges 108a. The process is continued until all bond pad edges 108 are bonded to a wire 192.

While the above-described process uses a laser as its heating source given its precision, other heating sources are possible. The time it takes to perform the above-described process may be reduced, for example by adding more heating sources and heating multiple bond pad edge sites simultaneously. FIG. 21 illustrates an example where multiple lasers 198 are used to form bonds 196 at each bond pad edge 108a in a column simultaneously.

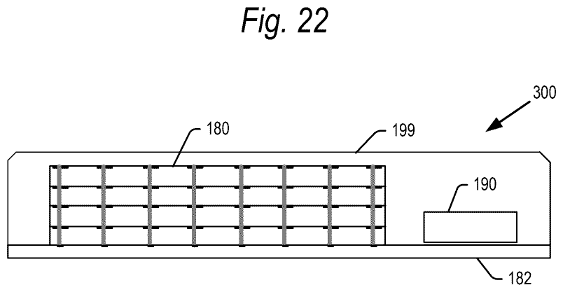

In a final step 230, the semiconductor device 180 and controller 190 may be encapsulated in mold compound 199 to form a finished semiconductor package 300 as shown in FIG. 22. The encapsulation step 230 may be performed by positioning the substrate 182 within a mold chase, and injecting liquid mold compound over the device 180 and controller 190. Other encapsulation processes may be used, including for example FFT (Flow Free Thin) compression molding, in further embodiments.

In summary, an example of the present technology relates to a semiconductor wafer comprising: a first major surface; a second major surface opposed to the first major surface; a plurality of semiconductor die comprising integrated circuits formed in the first major surface of the wafer; a kerf area comprising first and second sets of kerf lines, the first and second sets of kerf lines providing designated areas within which semiconductor die of the plurality of semiconductor die are separated from each other along dicing lines; and a plurality of die bond pads, the die bond pads comprising at least a portion extending into the first set of kerf lines and across a dicing line of the dicing lines.

In a further example, the present technology relates to a semiconductor die formed from a semiconductor wafer, the semiconductor die comprising: a first major surface; a second major surface opposed to the first major surface; integrated circuits formed adjacent the first major surface within an active area; and a plurality of die bond pads formed at least partially outside the active area.

In a further example, the present technology relates to a semiconductor package, comprising: a substrate; a plurality of stacked memory die mounted to the substrate, a semiconductor die of the stacked memory die comprising: integrated circuits formed adjacent the first major surface within an active area, a plurality of die bond pads formed at least partially outside the active area and having severed edges at an edge of the semiconductor die outside of the active area; and a controller die electrically connected to the stacked memory die for controlling the transfer of data to and from the stacked memory die.

In another example, the present technology relates to a semiconductor die formed from a semiconductor wafer, the semiconductor die comprising: a first major surface; a second major surface opposed to the first major surface; integrated circuits formed adjacent the first major surface within an active area; and pad means for transferring signals to and from the integrated circuits, the pad means having severed edges at an edge of the semiconductor die.

In a further example, the present technology relates to a semiconductor die formed from a semiconductor wafer, the semiconductor die comprising: a first major surface; a second major surface opposed to the first major surface; integrated circuits located within the first major surface; and a plurality of die bond pads having severed edges at an edge of the semiconductor die.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a plurality of stacked memory dies mounted to the substrate, each memory die of the plurality of stacked memory dies comprising die bond pads exposed at a vertical edge of the memory die, the vertical edges comprising the exposed die bond pads aligned with each other on a vertical face of the plurality of stacked memory dies; and
vertical bond wires electrically coupled to the exposed die bond pads on the vertical face of the plurality of stacked memory dies.

2. The semiconductor device of claim 1, wherein the plurality of stacked memory die are stacked one on top of each other in a cube configuration.

3. The semiconductor device of claim 1, wherein the vertical bond wires comprise non-contact soldered wire bonds.

4. The semiconductor device of claim 1, wherein the vertical bond wires comprise a vertical wire mounted on and extending from the substrate.

5. The semiconductor device of claim 4, wherein the vertical bond wires are affixed to columns of the exposed die bond pads.

6. The semiconductor device of claim 1, further comprising a plurality of contact pads on the substrate, the vertical bond wires comprising bond wires extending between the plurality of contact pads and a memory die of the plurality of stacked memory dies.

7. The semiconductor device of claim 6, further comprising a ball bond formed on a contact pad of the plurality of contact pads, a bond wire of the bond wires extending up from the ball bond.

8. The semiconductor device of claim 1, wherein the exposed die bond pad edges are arranged in columns on the vertical face.

9. The semiconductor device of claim 8, wherein bond wires bond the die bond pad edges in each column to each other.

10. The semiconductor device of claim 1, further comprising a controller die electrically connected to the stacked memory dies for controlling the transfer of data to and from the stacked memory dies.

11. The semiconductor device of claim 1, further comprising a residual portion of each die that is severed to define the exposed die bond pads, wherein the residual portion of each die is discarded.

12. A semiconductor device, comprising:
a substrate;
a plurality of memory dies mounted to the substrate, each memory die comprising a plurality of die bond pads, and each memory die diced from a wafer by first cuts along a y-axis and second cuts along the x-axis, the x-axis cuts passing through the plurality of die bond pads to leave a portion of the die bond pads exposed at a vertical edge of the semiconductor die, and wherein the plurality of memory dies are stacked in a cube with the vertical edges of the plurality of memory dies together defining a planer vertical face of the plurality of stacked memory dies; and
vertical bond wires electrically coupled to the exposed die bond pads on the vertical face of the plurality of stacked memory dies.

13. The semiconductor device of claim 12, wherein the vertical bond wires comprise non-contact soldered wire bonds.

14. The semiconductor device of claim 12, wherein the vertical bond wires comprise a vertical wire mounted on and extending from the substrate.

15. The semiconductor device of claim 14, wherein the vertical bond wires are affixed to columns of the exposed die bond pads.

16. The semiconductor device of claim 15, wherein the vertical bond wires are spaced from the vertical edge apart from the bond at the exposed die bond pads.

17. The semiconductor device of claim 12, further comprising a plurality of contact pads on the substrate, the vertical bond wires comprising bond wires extending between the plurality of contact pads and a memory die of the plurality of stacked memory dies.

18. The semiconductor device of claim 17, further comprising a ball bond formed on a contact pad of the plurality of contact pads, a bond wire of the bond wires extending up from the ball bond.

19. The semiconductor device of claim 12, wherein the exposed die bond pad edges are arranged in columns on the vertical face and wherein bond wires bond the die bond pad edges in each column to each other.

20. A semiconductor device, comprising:
a substrate;
a plurality of stacked memory dies mounted to the substrate, each memory die of the plurality of stacked memory dies comprising die bond pads exposed at a vertical edge of the memory die, the vertical edges comprising the exposed die bond pads aligned with each other on a vertical face of the plurality of stacked memory dies; and
wire bond means on the vertical face for electrically coupling the plurality of stacked memory dies to each other.
